(19) United States
(12) Patent Application Publication
(10) Pub. No.: US 2025/0336770 A1
(43) Pub. Date: Oct. 30, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ke-Gang WEN, Hsinchu (TW); Yu-Bey WU, Hsinchu (TW); I-Chang LEE, Hsinchu (TW); Hsin-Feng CHEN, Yilan (TW); Tsung-Chieh HSIAO, Changhua (TW); Liang-We WANG, Hsinchu (TW); Ying-Lin LAI, Miaoli (TW); Chih-Pin CHIU, Hsinchu (TW); Li-Yu LEE, New Taipei (TW); Cheng-Hao YEH, Taichung (TW)

(21) Appl. No.: 18/435,093

(22) Filed: Feb. 7, 2024

Related U.S. Application Data
(60) Provisional application No. 63/591,188, filed on Oct. 18, 2023.

(51) Int. Cl. H01L 23/48; H01L 21/768; H01L 23/58; H01L 25/065

(52) U.S. Cl. CPC H01L 23/481; H01L 21/76804; H01L 21/76831; H01L 21/76844; H01L 21/76846; H01L 21/76877; H01L 23/585; H01L 25/0657; H01L 2225/06541

(57) ABSTRACT

A semiconductor device structure and methods of forming the same are described. The structure includes a through silicon via disposed through a dielectric material, an interconnection structure, and a substrate. The through silicon via has a top surface having a first diameter and a portion located in the substrate having a second diameter, and the first diameter is substantially greater than the second diameter. The structure further includes an alloy portion surrounding the through silicon via, a barrier layer surrounding the alloy portion, and a liner surrounding the barrier layer. The through silicon via, the alloy portion, the barrier layer, and the liner together have a funnel shaped cross-section.

### CROSS-REFERENCE TO RELATED APPLICATIONS

This application claims priority to U.S. Provisional Application No. 63/591,188, filed on Oct. 18, 2023, the contents of which are hereby incorporated by reference in their entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for even smaller electronic devices has grown recently, there has grown a need for smaller and more creative packaging techniques of semiconductor dies.

As semiconductor technologies further advance, stacked semiconductor devices, e.g., 3D integrated circuit (3DIC) packages, have emerged as an effective alternative to further reduce the physical size of a semiconductor device. In a stacked semiconductor device, active circuits such as logic, memory, processor circuits, and the like are manufactured on different semiconductor wafers. Two or more semiconductor components may be installed on top of one another to further reduce the form factor of the semiconductor device.

The high level of integration of advanced packaging technologies enables production of semiconductor devices with enhanced functionalities and small footprints, which is advantageous for small form factor devices such as mobile phones, tablets and digital music players. Another advantage is the shortened length of the conductive paths connecting the interoperating parts within the semiconductor device. This improves the electrical performance of the semiconductor device, since shorter routing of interconnections between circuits yields faster signal propagation and reduced noise and cross-talk.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are cross-sectional side views of various stages of manufacturing a semiconductor device structure, in accordance with some embodiments.

FIGS. 2A and 2B are top views of the semiconductor device structure, in accordance with some embodiments.

FIGS. 3A-3C are cross-sectional side views of various stages of manufacturing the semiconductor device structure, in accordance with alternative embodiments.

FIGS. 4A-4C are cross-sectional side views of various stages of manufacturing the semiconductor device structure, in accordance with alternative embodiments.

FIGS. 5A and 5B are cross-sectional side views of a 3DIC package including a through silicon via (TSV) of the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

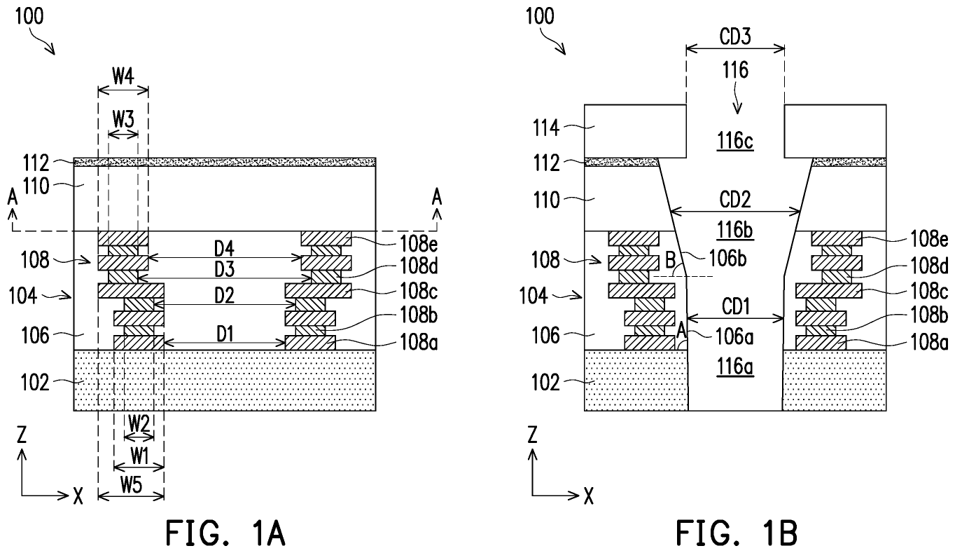

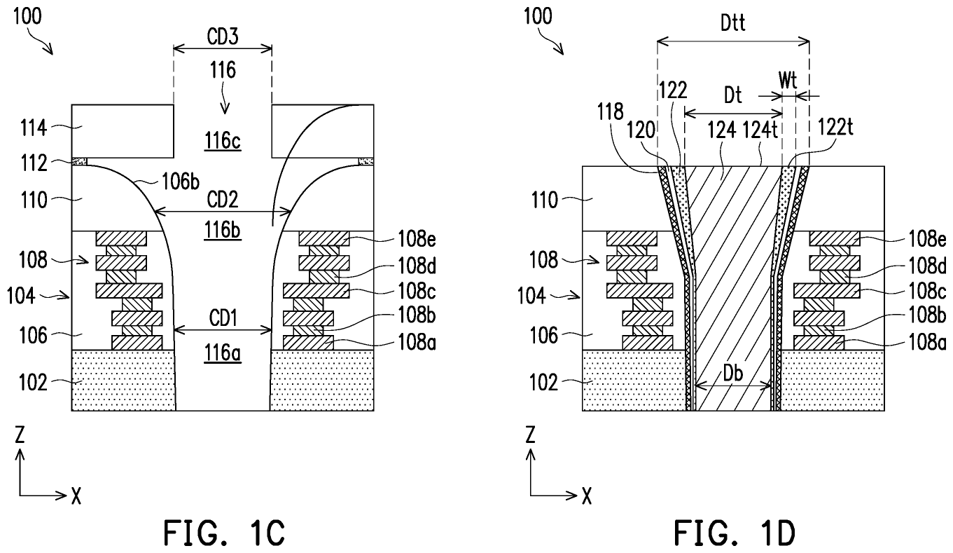

FIGS. 1A-1D are cross-sectional side views of various stages of manufacturing a semiconductor device structure 100, in accordance with some embodiments. As shown in FIG. 1A, the semiconductor device structure 100 includes a substrate 102, such as a semiconductor wafer or a semiconductor die. The substrate 102 may be a semiconductor substrate, such as silicon, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. Active and/or passive devices, such as transistors, diodes, capacitors, resistors, etc., may be formed in and/or on the substrate 102.

In some embodiments, the substrate 102 has a first region shown in FIG. 1A and a second region (not shown). Different features can be formed in the first region and the second region. For example, a guard ring and a through silicon via (TSV) may be formed in the first region. No active or passivation device is formed in the first region, or at least in the regions where the TSV will be formed. The active and passive devices may be formed in the second region and other regions of the substrate 102 that are not shown in FIG. 1A. Although only one first region is illustrated for clarity, those skilled in the art will recognize that multiple such first regions can be formed on a typical integrated circuit, with different configurations. For instance, in some embodiments, first regions could be dispersed amongst multiple second regions, whereas in other embodiments, a single first region or array of first regions could be formed about the periphery of a second region.

In some embodiments, as shown in FIG. 1A, the semiconductor device 100 includes an interconnection structure 104 over the substrate 102. The interconnection structure 104 may include metallization features in one or more dielectric layers 106. The metallization features may include metal lines (not shown) distributing in the dielectric layers 106 and vias (not shown) that connect the metal lines at different levels. The metal lines and vias may be located in the second region for providing power and signal to the active and passive devices. The metallization features may include copper, tungsten, cobalt, ruthenium, their alloys, or a combination thereof. In some embodiments, the metal lines and vias may further include a diffusion barrier layer (not shown). The diffusion barrier layer may include titanium, titanium nitride, tantalum, tantalum nitride, or a combination thereof. In some embodiments, the interconnection structure 104 may be formed by one or more single damascene processes, one or more dual damascene processes, or a combination thereof.

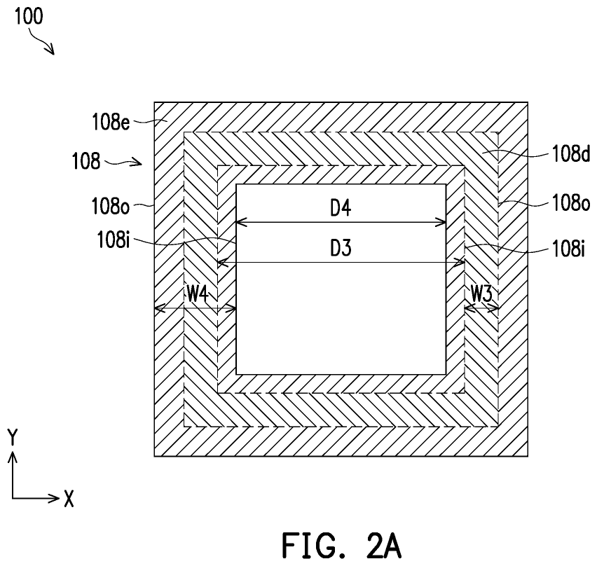

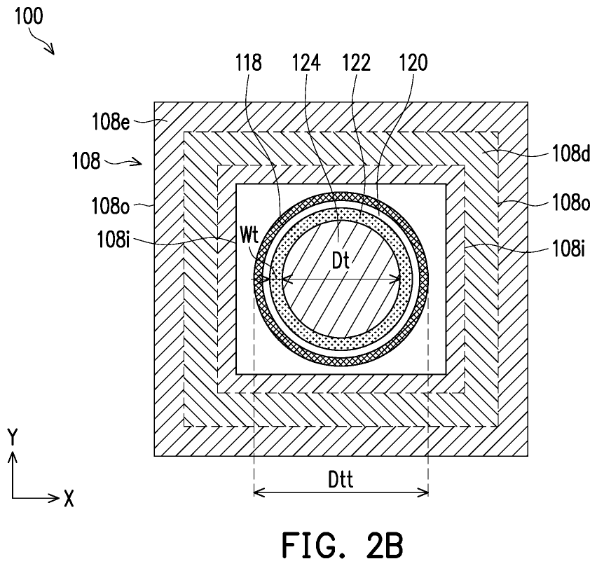

As shown in FIG. 1A, a guard ring 108 is disposed in the interconnection structure 104 in the first region. The guard ring 108 includes a stack of closed-loop structures 108a-e. FIG. 2A is a top view of the semiconductor device structure 100 taken along line A-A of FIG. 1A. The dielectric layers 106 are omitted in FIG. 2A for clarity. As shown in FIGS. 1A and 2A, each closed-loop structure 108a-e is a frame-like structure. In some embodiments, each closed-loop structure 108a-e is an annular structure. As shown in FIG. 2A, the closed-loop structure 108e is disposed on the closed-loop structure 108d. Each closed-loop structure 108d, 108e (and closed-loop structure 108a-c) includes an inner edge 108i and an outer edge 1080. In some embodiments, the inner edge 108i and the outer edge 1080 each includes four sides that form a rectangular shape. In some embodiments, the inner edge 108i and the outer edge 1080 each forms a circular shape. Each closed-loop structure 108d, 108e (and closed-loop structure 108a-c) includes a dimension (W1-W5) from the inner edge 108i to the outer edge 1080 along the X direction. The dimensions of the closed-loop structures 108a-e are different. In some embodiments, as shown in FIGS. 1A and 2A, the dimension W1 of the closed-loop structures 108a is substantially greater than the dimension W2 of the closed-loop structures 108b located above corresponding closed-loop structures 108a, the dimension W3 of the closed-loop structures 108d is substantially less than the dimension W4 of the closed-loop structures 108e located above corresponding closed-loop structures 108d, and the dimension W5 of the closed-loop structure 108c is substantially greater than the dimensions W1, W2, W3, W4 of the closed-loop structures 108a, 108b, 108d, 108e, respectively. In some embodiments, the guard ring 108 includes alternating closed-loop structures 108a, 108b, one closed-loop structure 108c disposed on the topmost closed-loop structure of the alternating closed-loop structures 108a, 108b, and alternating closed-loop structures 108d, 108e disposed on the closed-loop structure 108c. The numbers of the closed-loop structures 108a-e shown in FIG. 1A are merely examples and are not intended to be limiting. In some embodiments, the guard ring 108 includes a plurality of alternating closed-loop structures 108a, 108b and a plurality of alternating closed-loop structures 108d, 108e. The plurality of alternating closed-loop structures 108a, 108b and the plurality of alternating closed-loop structures 108d, 108e are separated by the closed-loop structure 108c. In some embodiments, the dimension W1 of the closed-loop structure 108a and the dimension W4 of the closed-loop structure 108e are substantially the same, and the dimension W2 of the closed-loop structure 108b and the dimension W3 of the closed-loop structure 108d are substantially the same. In some embodiments, the closed-loop structures 108a, 108c, 108e are formed at the same time as the metal lines in the second region, and the closed-loop structures 108b, 108d are formed at the same time as the metal vias in the second region.

In some embodiments, a distance D1 is between two opposite sides of the inner edge 108i of the closed-loop structure 108a along the X direction (or along the Y direction), a distance D2 is between two opposite sides of the inner edge 108i of the closed-loop structure 108b along the X direction (or along the Y direction), a distance D3 is between two opposite sides of the inner edge 108i of the closed-loop structure 108d along the X direction (or along the Y direction), and a distance D4 is between two opposite sides of the inner edge 108i of the closed loop structure 108e along the X direction (or along the Y direction). In some embodiments, the closed-loop structures 108a-e are annular structures, and the distances D1, D2, D3, D4 are inner diameters of the closed-loop structures 108a, 108b, 108d, 108e, respectively. In some embodiments, the distance D1 is less than the distance D2, and the distance D4 is less than the distance D3. In some embodiments, in order to enlarge a top portion of a subsequently formed through silicon via (TSV) 124 (FIG. 1D), the distances D3, D4 are substantially greater than the distances D2, D1, respectively.

In some embodiments, the closed-loop structures 108a are aligned in the Z direction, the closed-loop structures 108b are aligned in the Z direction, the closed-loop structures 108d are aligned in the Z direction, and the closed-loop structures 108e are aligned in the Z direction. In other words, the outer edges 1080 and the inner edges 108i of the closed-loop structures 108a are aligned, the outer edges 1080 and the inner edges 108i of the closed-loop structures 108b are aligned, the outer edges 1080 and the inner edges 108i of the closed-loop structures 108d are aligned, and the outer edges 1080 and the inner edges 108i of the closed-loop structures 108e are aligned, as shown in FIG. 1A. The closed-loop structures 108d are not aligned with the closed-loop structures 108b due to the enlarged distance D3, and the closed-loop structures 108e are not aligned with the closed-loop structures 108a due to the enlarged distance D4. In other words, the closed-loop structures 108a and the closed-loop structures 108e are offset, and the closed-loop structures 108b and the closed-loop structures 108d are offset. In order to provide contact with both the closed-loop structure 108b and the closed loop structure 108e, the dimension W5 of the closed-loop structure 108c is enlarged. In some embodiments, the dimension W5 of the closed-loop structure 108c is greater than the dimensions W1, W2, W3, W4 of the closed-loop structures 108a, 108b, 108d, 108e, respectively.

A dielectric material 110 is deposited on the interconnection structure 104, and a dielectric layer 112 is deposited on the dielectric material 110. In some embodiments, the dielectric material 110 is undoped silicate glass (USG), and the dielectric layer 112 is a SiC layer. The dielectric material 110 may have a thickness ranging from about 400 nm to about 1000 nm. In some embodiments, in the second region, conductive features, such as redistribution layers (RDLs) are formed in the dielectric material 110.

As shown in FIG. 1B, a resist layer 114 is deposited on the dielectric layer 112, and an opening 116 is formed in the resist layer 114, the dielectric layer 112, the dielectric material 110, the interconnection structure 104, and the substrate 102. In some embodiments, the opening 116 includes a bottom portion 116a, a middle portion 116b, and a top portion 116c. In some embodiments, the bottom portion 116a is defined by side surfaces of the substrate 102 and side surfaces of the dielectric layers 106 in which the closed-loop structures 108a-c are located therein. The middle portion 116b is defined by side surfaces of the dielectric layers 106 in which the closed-loop structures 108d-e are located therein, side surfaces of the dielectric material 110, and side surfaces of the dielectric layer 112. The top portion 116c is defined by the side surfaces of the resist layer 114. In some embodiments, the bottom portion 116a has a substantially constant critical dimension CD1, the middle portion 116b has a varying critical dimension CD2, and the top portion 116c has a substantially constant critical dimension CD3. In some embodiments, the varying critical dimension CD2 increases in a direction away from the substrate 102, and the largest critical dimension CD2 may range from 1.15 times the critical dimension CD1 to about 2.5 times the critical dimension CD1. In some embodiments, the substantially constant critical dimension CD3 is substantially the same as the substantially constant critical dimension CD1.

The opening 116 having the bottom portion 116a, the middle portion 116b, and the top portion 116c may be formed by one or more processes, such as one or more etch processes. By utilizing different etchants, such as SF₆, CF₄, or O₂, and tuning the plasma bias, such as from about 0 V to about 900 V, the one or more etching processes may be more or less isotropic. As a result, undercut below the resist layer 114 may occur, and the opening 116 includes the middle portion 116b having a varying critical dimension CD2. For example, initially, the one or more etch processes may be substantially anisotropic, so the opening 116 may have a constant critical dimension. Then, the one or more etch processes become more isotropic by changing the etchant and/or tuning the plasma bias (e.g., reducing the plasma bias), and undercut below the resist layer 114 may occur. In some embodiments, the top portion 116c of the opening 116 is first formed using a photolithography and one or more etch processes to expose a portion of the dielectric layer 112. The resist layer 114 may be a single layer photoresist or a tri-layer photoresist. An exemplary tri-layer photoresist may include a bottom layer, a middle layer disposed over the bottom layer, and a photosensitive top layer disposed over the middle layer. The bottom layer may be a bottom anti-reflective coating (BARC) layer, the middle layer may be a silicon-containing inorganic polymer that provides anti-reflective properties and/or hard mask properties for a photolithography process, and the photosensitive top layer may be a DUV resist (KrF) resist, an argon fluoride (ArF) resist, an EUV resist, an electron beam (e-beam) resist, or an ion beam resist. The photolithography process and the one or more etch processes remove a portion of the resist layer 114. Then, another one or more etch processes are performed to form the middle portion 116b and bottom portion 116a of the opening 116. The one or more etch processes to form the middle portion 116b and the bottom portion 116a may be selective etch processes that do not substantially affect the resist layer 114. In some embodiments, the one or more etch processes to form the middle portion 116b and the bottom portion 116a first form the bottom portion 116a and the middle portion 116b having the same critical dimension as the bottom portion 116a. Next, changes in the process conditions, such as lowering the plasma bias, and/or changes in the etchants, are performed to make the etch processes more isotropic. As a result, the critical dimension CD2 of the middle portion 116b is increased in a way shown in FIGS. 1B and 1C. In some embodiments, the increased critical dimension CD2 causes the opening 116 to have a funnel shape.

In some embodiments, the middle portion 116b of the opening 116 may be surrounded by the closed-loop structures 108d, 108e. The increased distances D3 and D4 of the closed-loop structures 108d, 108e, respectively, help to accommodate the varying critical dimension CD2 that increases in the direction away from the substrate 102. The bottom portion 116a of the opening 116 may be surrounded by the closed-loop structures 108a, 108b, 108c. Because the critical dimension CD1 is substantially constant, the distances D1 and D2 of the closed-loop structures 108a, 108b do not need to be increased. As a result, the area on the substrate 102 occupied by the closed-loop structure 108a is not enlarged, and the number of the active devices or passive devices in the second region may not be reduced.

In some embodiments, the side surface 106a of the dielectric layers 106 defining the bottom portion 116a of the opening 116 has a substantially linear cross-section, as shown in FIG. 1B, and the side surface 106a and a major surface of the substrate 102 form an angle A. The side surface 106b of the dielectric layers 106 defining the middle portion 116b of the opening 116 has a substantially linear cross-section, and the side surface 106b and a plane substantially parallel to the major surface of the substrate 102 form an angle B. The angle A is substantially greater than the angle B. In some embodiments, the angle A ranges from about 88 degrees to about 90 degrees, and the angle B ranges from about 80 degrees to about 87 degrees.

In some embodiments, the side surface 106b and the side surface of the dielectric material 110 exposed to the middle portion 116b of the opening 116 each has a substantially linear cross-section, as shown in FIG. 1B. Thus, in some embodiments, the varying critical dimension CD2 may be increasing in the direction away from the substrate 102 at a constant rate. In other words, the relationship between the distance in the Z direction and the varying critical dimension CD2 is linear. In some embodiments, the side surface 106b and the side surface of the dielectric material 110 exposed to the middle portion 116b of the opening 116 each has a substantially curved cross-section, as shown in FIG. 1C. For example, the side surface 106b and the side surface of the dielectric material 110 exposed to the middle portion 116b of the opening 116 together has a convex shape. Thus, in some embodiments, the varying critical dimension CD2 may be increasing in the direction away from the substrate 102 at an exponential rate. In other words, the relationship between the distance in the Z direction and the varying critical dimension CD2 is exponential. The shapes of the side surface 106b and the side surface of the dielectric material 110 may be controlled by the one or more etch processes. After the formation of the opening 116, the resist layer 114 may be removed. The resist layer 114 may be removed by a selective process that does not substantially affect the other materials of the semiconductor device structure 100.

As shown in FIG. 1D, a liner 118, a barrier layer 120, and the TSV 124 are formed in the opening 116. The liner 118 includes a dielectric material, such as an oxide or a nitride, and may be formed by a conformal process, such as atomic layer deposition (ALD). After forming the liner 118 in the opening 116 covering the side surfaces exposed to the opening 116, the barrier layer 120 is formed on the liner 118 in the opening 116. The barrier layer 120 includes a metal or a metal nitride, such as Ti, TiN, Ta, TaN, or other suitable material. The TSV 124 includes a metal, such as copper. In some embodiments, during an annealing process, the barrier layer 120 and the TSV 124 react to form an alloy portion 122, as shown in FIGS. 1D and 2B. The alloy portion 122 may have a varying thickness, as shown in FIG. 1D. For example, the thickness of the alloy portion 122 decreases in a direction towards the substrate 102, as a result of the annealing process (heating from the top). FIG. 2B is a top view of the semiconductor device structure 100 taken along line A-A of FIG. 1A. The dielectric layers 106 are omitted in FIG. 2B for clarity. As shown in FIG. 2B, the TSV 124 may have a circular shape when viewed from the top, the alloy portion 122 may be annular when viewed from the top, the barrier layer 120 may be annular when viewed from the top, and the liner 118 may be annular when viewed from the top. The TSV 124, the alloy portion 122, the barrier layer 120, and the liner 118 may have any suitable shape. In some embodiments, because the opening 116 has a funnel shape, the TSV 124, the alloy portion 122, the barrier layer 120, and the liner 118 together may have a funnel shaped cross-section. In some embodiments, the TSV 124 has a funnel shaped cross-section.

Referring back to FIG. 1D, in some embodiments, the alloy portion 122 includes Cu/Ti alloy, and the contact resistance Rc of the CuTi alloy is substantially greater than the Rc of the copper of the TSV 124. Thus, by increasing the distances D3, D4 of the closed-loop structures 108d, 108e, respectively, the critical dimension CD2 of the middle portion 116b of the opening 116 is increased. As a result, the area of a top surface 124t of the TSV 124 is enlarged, which in turn reduces the contact resistance Rc. In some embodiments, the Rc is reduced by 20 percent compared to conventional TSVs. In some embodiments, a diameter Dt of the top surface 124t of the TSV 124 is substantially the same as or greater than a diameter Db of the portion of the TSV 124 located in the substrate 102, as shown in FIG. 1D. As shown in FIGS. 1D and 2B, a top surface 122t of the alloy portion 122 has a width Wt. In some embodiments, the width Wt is about three percent to about five percent of the sum of the width Wt and the diameter Dt. In some embodiments, the top surfaces of the liner 118, the barrier layer 120, the alloy portion 122, and the TSV 124 have a total diameter Dtt, and the total diameter Dtt may be about 1.15 times to about 2.5 times the diameter Db of the portion of the TSV 124 located in the substrate 102.

FIG. 1D illustrates the liner 118, the barrier layer 120, the alloy portion 122, and the TSV 124 being formed in the opening 116 shown in FIG. 1B. In some embodiments, the liner 118, the barrier layer 120, the alloy portion 122, and the TSV 124 are formed in the opening 116 shown in FIG. 1C. After the formation of the TSV 124, the dielectric layer 112 may be removed. In some embodiments, the dielectric layer 112 may be removed by a planarization process, such as a chemical mechanical polishing (CMP) process.

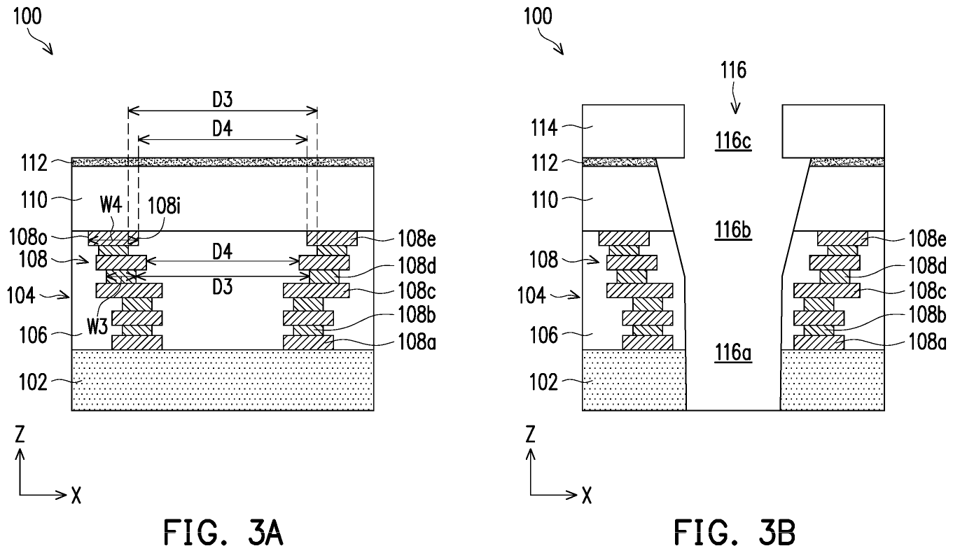

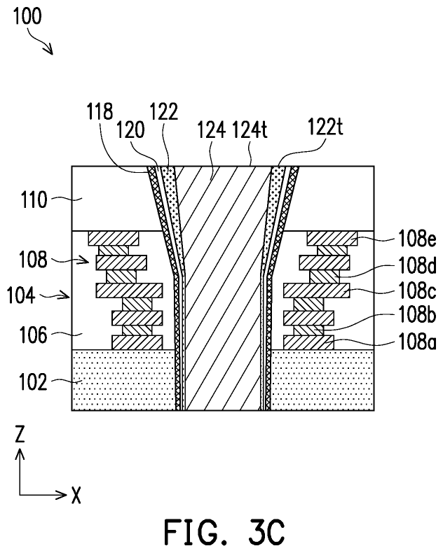

FIGS. 3A-3C are cross-sectional side views of various stages of manufacturing the semiconductor device structure 100, in accordance with alternative embodiments. As shown in FIG. 3A, the guard ring 108 includes the closed-loop structures 108a-e. In some embodiments, the distances D3, D4 of the closed-loop structures 108d, 108e, respectively, are increasing in a direction away from the substrate 102. In other words, the distance D3 is increasing in a direction away from the substrate 102, and the distance D4 is increasing in a direction away from the substrate 102. For example, the closed-loop structure 108d disposed on the closed-loop structure 108c has a first distance D3, and the closed-loop structure 108d disposed on the closed-loop structure 108e that is disposed on the closed-loop structure 108d having the first distance D3 has a second distance D3 substantially greater than the first distance D3. Similarly, the closed-loop structure 108e disposed on the closed-loop structure 108d that is disposed on the closed-loop structure 108c has a first distance D4, and the closed-loop structure 108e disposed on the closed-loop structure 108d that is disposed on the closed-loop structure 108e having the first distance D4 has a second distance D4 substantially greater than the first distance D4. In some embodiments, the closed-loop structures 108a are aligned in the Z direction, the closed-loop structures 108b are aligned in the Z direction, the closed-loop structures 108d are not aligned in the Z direction, and the closed-loop structures 108e are not aligned in the Z direction. In other words, the outer edges 1080 and the inner edges 108i of the closed-loop structures 108a are aligned, the outer edges 1080 and the inner edges 108i of the closed-loop structures 108b are aligned, the outer edges 1080 and the inner edges 108i of the closed-loop structures 108d are not aligned, and the outer edges 1080 and the inner edges 108i of the closed-loop structures 108e are not aligned, as shown in FIG. 3A. For example, the outer edges 1080 of the closed-loop structures 108d are expanding laterally outward in a direction away from the substrate 102, and the inner edges 108i of the closed-loop structures 108d are expanding laterally outward in a direction away from the substrate 102. Similarly, the outer edges 1080 of the closed-loop structures 108e are expanding laterally outward in a direction away from the substrate 102, and the inner edges 108i of the closed-loop structures 108e are expanding laterally outward in a direction away from the substrate 102. In some embodiments, the dimensions W3, W4 of the closed-loop structures 108d, 108e, respectively, shown in FIG. 3A may be the same as the dimensions W3, W4 of the closed-loop structures 108d, 108e, respectively, shown in FIG. 1A.

As shown in FIG. 3B, the resist layer 114 is formed on the dielectric layer 112, and the opening 116 is formed in the resist layer 114, the dielectric layer 112, the dielectric material 110, the interconnection structure 104, and the substrate 102. The opening 116 may include the bottom portion 116a, the middle portion 116b, and the top portion 116c. Because of the location of the closed-loop structures 108d, 108e, the middle portion 116b of the opening 116 with the increasing critical dimension CD2 (FIG. 1B) does not expose the closed-loop structures 108d, 108e. The opening 116 may have the shape shown in FIG. 3B or the shape shown in FIG. 2C.

As shown in FIG. 3C, the liner 118, the barrier layer 120, the alloy portion 122, and the TSV 124 are formed in the opening 116. The diameter Dt of the top surface 124t of the TSV 124 is substantially the same as or greater than the diameter Db of the portion of the TSV 124 located in the substrate 102. With the large top surface 124t of the TSV 124, the Rc is reduced.

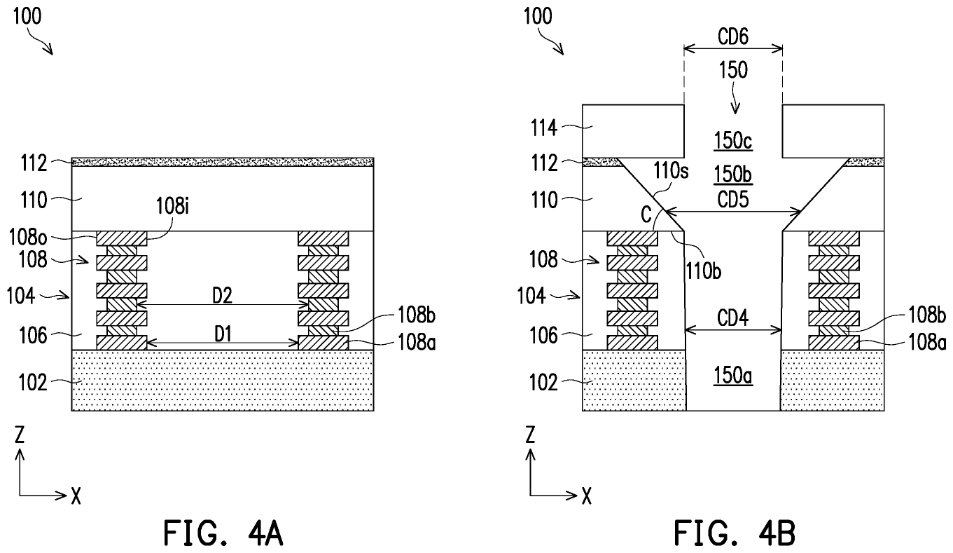

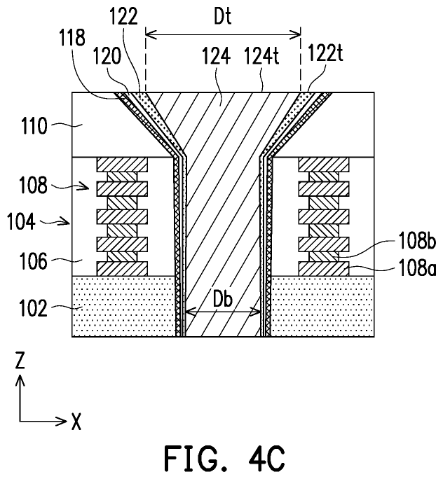

FIGS. 4A-4C are cross-sectional side views of various stages of manufacturing the semiconductor device structure 100, in accordance with alternative embodiments. As shown in FIG. 4A, the guard ring 108 includes the alternating closed-loop structures 108a, 108b. The closed-loop structures 108c-e are not present in the guard ring 108. In some embodiments, the closed-loop structures 108a are aligned in the Z direction, and the closed-loop structures 108b are aligned in the Z direction. In other words, the outer edges 1080 and the inner edges 108i of the closed-loop structures 108a are aligned, and the outer edges 1080 and the inner edges 108i of the closed-loop structures 108b are aligned. The distances D1 and the distances D2 are substantially constant in a direction away from the substrate 102.

As shown in FIG. 4B, the resist layer 114 is deposited on the dielectric layer 112, and an opening 150 is formed in the resist layer 114, the dielectric layer 112, the dielectric material 110, the interconnection structure 104, and the substrate 102. In some embodiments, the opening 150 includes a bottom portion 150a, a middle portion 150b, and a top portion 150c. In some embodiments, the bottom portion 150a is defined by side surfaces of the substrate 102 and the dielectric layers 106. The middle portion 150b is defined by side surfaces of the side surfaces of the dielectric material 110 and the dielectric layer 112. The top portion 150c is defined by the side surfaces of the resist layer 114. In some embodiments, the bottom portion 150a has a substantially constant critical dimension CD4, the middle portion 150b has a varying critical dimension CD5, and the top portion 150c has a substantially constant critical dimension CD6. In some embodiments, the varying critical dimension CD5 increases in a direction away from the substrate 102 and may range from 1.15 times the critical dimension CD1 to about 2.5 times the critical dimension CD1. In some embodiments, the substantially constant critical dimension CD6 is substantially the same as the substantially constant critical dimension CD4.

In some embodiments, the critical dimension CD5 of the middle portion 150b of the opening 150 is increasing, so the top surface 124t of the TSV 124 (FIG. 4C) is enlarged, which in turn reduces the Rc. The increasing critical dimension CD5 of the middle portion 150b of the opening 150 can cause the opening 150 to have a funnel shape. In some embodiments, the side surface 110s of the dielectric material 110 defining the middle portion 150b of the opening 150 has a substantially linear cross-section, as shown in FIG. 4B, and the side surface 110s and a bottom surface 110b of the dielectric material 110 form an angle C. The angle C is an acute angle ranging from about 45 degrees to about 87 degrees. In some embodiments, the side surface 110s of the dielectric material 110 defining the middle portion 150b of the opening 150 has a curved cross-section, such as a convex shaped cross-section.

The opening 150 may be formed by the same processes as the opening 116. By adjusting the etchants and/or plasma bias, the undercut in the dielectric material 110 under the resist layer 114 can be formed. The resist layer 114 is removed after the formation of the opening 150.

As shown in FIG. 4C, the liner 118, the barrier layer 120, the alloy portion 122, and the TSV 124 are formed in the opening 150. The diameter Dt of the top surface 124t of the TSV 124 is substantially greater than the diameter Db of the portion of the TSV 124 located in the substrate 102. With the large top surface 124t of the TSV 124, the Rc is reduced. In some embodiments, because the opening 150 has a funnel shape, the TSV 124, the alloy portion 122, the barrier layer 120, and the liner 118 together may have a funnel shaped cross-section. In some embodiments, the TSV 124 has a funnel shaped cross-section.

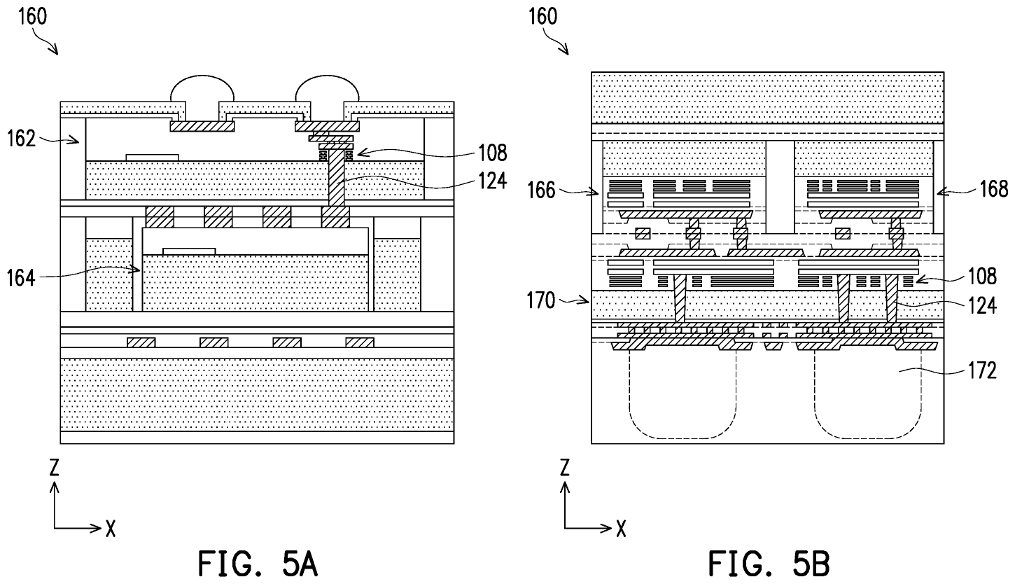

FIGS. 5A and 5B are cross-sectional side views of a 3DIC package 160 including the TSV 124 of the semiconductor device structure 100, in accordance with some embodiments. As shown in FIG. 5A, the 3DIC package 160 is a system-on-integrated chip (SoIC) with face-to-back (F2B) bonding. The 3DIC package 160 includes a first die 162 disposed over a second die 164. The TSV 124 is utilized to electrically connect the first and second dies 162, 164. The TSV 124 is surrounded by the guard ring 108. The TSV 124 may be the TSV 124 shown in FIGS. 1D, 3C, 4C, and the guard ring 108 may be the guard ring 108 shown in FIGS. 1D, 3C, 4C. The alloy portion 122, the barrier layer 120, and the liner 118 may be omitted in FIG. 5A for clarity.

As shown in FIG. 5B, the 3DIC package 160 is a SoIC with face-to-face (F2F) bonding. The 3DIC package 160 includes a first die 166, and second die 168 disposed adjacent the first die 166, and a third die 170 disposed below the first and second dies 166, 168. One or more TSVs 124 are utilized to electrically connect the third die 170 to one or more micro bumps 172, which are electrically connected to a package substrate (not shown). The TSV 124 is surrounded by the guard ring 108. The TSV 124 may be the TSV 124 shown in FIGS. 1D, 3C, 4C, and the guard ring 108 may be the guard ring 108 shown in FIGS. 1D, 3C, 4C. The alloy portion 122, the barrier layer 120, and the liner 118 may be omitted in FIG. 5B for clarity.

Embodiments of the present disclosure provide a semiconductor device structure 100 including a TSV 124 having a top surface 124t having a diameter Dt substantially the same as or greater than a diameter Db of a portion of the TSV 124 located in the substrate 102. In some embodiments, closed-loop structures 108d, 108e located at the top of a guard ring 108 may be modified so a distance D3 or D4 between opposite sides of the inner edge 108i of the closed-loop structures 108d, 108e is increased. Some embodiments may achieve advantages. For example, the increased top surface 124t of the TSV 124 decreases the contact resistance.

An embodiment is a semiconductor device structure. The structure includes a through silicon via disposed through a dielectric material, an interconnection structure, and a substrate. The through silicon via has a top surface having a first diameter and a portion located in the substrate having a second diameter, and the first diameter is substantially greater than the second diameter. The structure further includes an alloy portion surrounding the through silicon via, a barrier layer surrounding the alloy portion, and a liner surrounding the barrier layer. The through silicon via, the alloy portion, the barrier layer, and the liner together have a funnel shaped cross-section.

Another embodiment is a semiconductor device structure. The structure includes a through silicon via disposed through a dielectric material, an interconnection structure, and a substrate and a guard ring surrounding the through silicon via. The guard ring includes a first closed-loop structure having a first inner edge, a first outer edge, and a first dimension between the first inner and outer edges. A first distance is between two opposite sides of the first inner edge. The guard ring further includes a second closed-loop structure disposed over the first closed-loop structure, and the second closed-loop structure has a second inner edge, a second outer edge, and a second dimension between the second inner and outer edges. The second dimension is substantially less than the first dimension, a second distance is between two opposite sides of the second inner edge, and the second distance is substantially greater than the first distance. The guard ring further includes a third closed-loop structure disposed over the second closed-loop structure, and the third closed-loop structure has a third inner edge, a third outer edge, and a third dimension between the third inner and outer edges. The third dimension is substantially the same as the first dimension, a third distance is between two opposite sides of the third inner edge, and the third distance is substantially greater than the first distance. The guard ring further includes a fourth closed-loop structure disposed over the third closed-loop structure, and the fourth closed-loop structure has a fourth inner edge, a fourth outer edge, and a fourth dimension between the fourth inner and outer edges. The fourth dimension is substantially the same as the second dimension, a fourth distance is between two opposite sides of the fourth inner edge, and the fourth distance is substantially greater than the second distance.

A further embodiment is a method. The method includes forming a guard ring in an interconnection structure. The forming of the guard ring includes depositing a first closed-loop structure, and the first closed-loop structure has a first outer edge. The forming of the guard ring further includes depositing a second closed-loop structure over the first closed-loop structure, and the second closed-loop structure has a second outer edge located laterally outward of the first outer edge. The forming of the guard ring further includes depositing a third closed-loop structure over the second closed-loop structure, and the third closed-loop structure has a third outer edge located laterally outward of the second outer edge. The method further includes forming an opening in the interconnection structure surrounded by the guard ring, and the opening includes a bottom portion having a first critical dimension, a middle portion having a second critical dimension, and a top portion having a third critical dimension. The first and third critical dimensions are substantially constant, and the second critical dimension varies. The method further includes depositing a through silicon via into the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a through silicon via disposed through a dielectric material, an interconnection structure, and a substrate, wherein the through silicon via has a top surface having a first diameter and a portion located in the substrate having a second diameter, and the first diameter is substantially greater than the second diameter;
an alloy portion surrounding the through silicon via;
a barrier layer surrounding the alloy portion; and
a liner surrounding the barrier layer, wherein the through silicon via, the alloy portion, the barrier layer, and the liner together have a funnel shaped cross-section.

2. The semiconductor device structure of claim 1, wherein the through silicon via comprises Cu, the barrier layer comprises Ti, and the alloy portion comprises Cu/Ti alloy.

3. The semiconductor device structure of claim 1, wherein the alloy portion has a top surface having a first width, and the first width is about three percent to about five percent of a sum of the first width and the first diameter.

4. The semiconductor device structure of claim 1, wherein top surfaces of the liner, the barrier layer, the alloy portion, and the through silicon via have a total diameter, and the total diameter is about 1.15 times to about 2.5 times the second diameter.

5. The semiconductor device structure of claim 1, further comprising a guard ring surrounding the through silicon via.

6. The semiconductor device structure of claim 5, wherein the guard ring comprises a plurality of closed-loop structures.

7. The semiconductor device structure of claim 6, wherein the plurality of closed-loop structures comprises:
a first closed-loop structure having a first inner edge, a first outer edge, and a first dimension between the first inner and outer edges;
a second closed-loop structure disposed over the first closed-loop structure, wherein the second closed-loop structure has a second inner edge, a second outer edge, and a second dimension between the second inner and outer edges; and
a third closed-loop structure disposed over the second closed-loop structure, wherein the third closed-loop structure has a third inner edge, a third outer edge, and a third dimension between the third inner and outer edges.

8. The semiconductor device structure of claim 7, wherein the first dimension and the third dimension are substantially the same.

9. The semiconductor device structure of claim 8, wherein the second dimension is substantially greater than the first and third dimensions.

10. The semiconductor device structure of claim 8, wherein a first distance between opposite sides of the first inner edge is substantially smaller than a second distance between opposite sides of the third inner edge.

11. The semiconductor device structure of claim 7, wherein the first, second, and third dimensions are substantially the same.

12. The semiconductor device structure of claim 11, wherein a first distance between opposite sides of the first inner edge is substantially smaller than a second distance between opposite sides of the second inner edge, which is substantially smaller than a third distance between opposite sides of the third inner edge.

13. A semiconductor device structure, comprising:
a through silicon via disposed through a dielectric material, an interconnection structure, and a substrate;
a guard ring surrounding the through silicon via, wherein the guard ring comprises:
a first closed-loop structure having a first inner edge, a first outer edge, and a first dimension between the first inner and outer edges, wherein a first distance is between two opposite sides of the first inner edge;
a second closed-loop structure disposed over the first closed-loop structure, wherein the second closed-loop structure has a second inner edge, a second outer edge, and a second dimension between the second inner and outer edges, wherein the second dimension is substantially less than the first dimension, a second distance is between two opposite sides of the second inner edge, and the second distance is substantially greater than the first distance;
a third closed-loop structure disposed over the second closed-loop structure, wherein the third closed-loop structure has a third inner edge, a third outer edge, and a third dimension between the third inner and outer edges, wherein the third dimension is substantially the same as the first dimension, a third distance is between two opposite sides of the third inner edge, and the third distance is substantially greater than the first distance; and
a fourth closed-loop structure disposed over the third closed-loop structure, wherein the fourth closed-loop structure has a fourth inner edge, a fourth outer edge, and a fourth dimension between the fourth inner and outer edges, wherein the fourth dimension is substantially the same as the second dimension, a fourth distance is between two opposite sides of the fourth inner edge, and the fourth distance is substantially greater than the second distance.

14. The semiconductor device structure of claim 13, further comprising a fifth closed-loop structure disposed between the second and third closed-loop structures.

15. The semiconductor device structure of claim 14, wherein the fifth closed-loop structure has a fifth inner edge, a fifth outer edge, and a fifth dimension between the fifth inner and outer edges, wherein the fifth dimension is substantially greater than the first dimension.

16. The semiconductor device structure of claim 14, further comprising an alloy portion surrounding the through silicon via.

17. The semiconductor device structure of claim 16, wherein the alloy portion comprises Cu/Ti alloy, and the through silicon via comprises Cu.

18. A method, comprising:
forming a guard ring in an interconnection structure, comprising:
depositing a first closed-loop structure, wherein the first closed-loop structure has a first outer edge;
depositing a second closed-loop structure over the first closed-loop structure, wherein the second closed-loop structure has a second outer edge located laterally outward of the first outer edge; and
depositing a third closed-loop structure over the second closed-loop structure, wherein the third closed-loop structure has a third outer edge located laterally outward of the second outer edge;
forming an opening in the interconnection structure surrounded by the guard ring, wherein the opening comprises a bottom portion having a first critical dimension, a middle portion having a second critical dimension, and a top portion having a third critical dimension, wherein the first and third critical dimensions are substantially constant, and the second critical dimension varies; and
depositing a through silicon via into the opening.

19. The method of claim 18, further comprising depositing a liner in the opening and depositing a barrier layer on the liner in the opening, wherein the through silicon via is deposited on the barrier layer.

20. The method of claim 19, further comprising forming an alloy portion between the barrier layer and the through silicon via.
